(19) United States
(12) Patent Application Publication
(10) Pub. No.: US 2016/0301369 A1
(43) Pub. Date: Oct. 13, 2016

(54) BAND OPTIMISED RF SWITCH LOW NOISE AMPLIFIER

(71) Applicants: EUGENE HEANEY, ROCHESTOWN (IE); JOHN O'SULLIVAN, CAMPBELL, CA (US)

(72) Inventors: EUGENE HEANEY, ROCHESTOWN (IE); JOHN O'SULLIVAN, CAMPBELL, CA (US)

(73) Assignee: FERFICS LIMITED, LITTLE ISLAND (IE)

(21) Appl. No.: 15/094,534

(22) Filed: Apr. 8, 2016

Related U.S. Application Data
(60) Provisional application No. 62/145,604, filed on Apr. 10, 2015.

(51) Int. Cl. H03F 1/42; H03F 3/195; H03F 3/45; H03F 1/52

(52) U.S. Cl. CPC H03F 1/42; H03F 1/52; H03F 3/195; H03F 3/45071; H03F 2203/45112; H03F 2200/111; H03F 2200/156; H03F 2200/153; H03F 2200/222; H03F 2200/294; H03F 2200/451

(57) ABSTRACT

An RF switching circuit is described. The RF switching circuit comprises an RF switch having multiple RF inputs and two or more switch outputs; a low noise amplifier (LNA) having two or more amplification branches, each amplification branch being associated with a corresponding switch output; and a bypass switching mechanism configured for selectively bypassing the amplification branches.

### FIELD OF THE INVENTION

The present disclosure relates to an RF switching circuit. In particular but not exclusively, the present disclosure relates to an RF switching circuit having an RF switch operable with a Low Noise Amplifier (LNA) that is optimised for performance across multiple frequency bands.

### BACKGROUND

RF Switch LNAs are key building block in front end of wireless systems and find many uses in applications such as mobile phones and wireless LANs. The low-noise amplifier is used to increase the dynamic range of a receiver. RF Switch LNA typically includes an RF switch that connects one of multiple input ports to the input of a low noise amplifier, LNA. The LNA is used to provide amplification when the signal level is weak. The LNA may be bypassed when the signal level is large to prevent overload of the LNA and saturation of the next stage amplifier. The output of the LNA provides a signal to the receiver that is of sufficient amplitude to meet a required system sensitivity.

Performance metrics such as noise figure, gain, linearity, input and output return loss are critical in RF Switch LNA design. Typically the signals that are connected to the input ports of the RF Switch LNA contain frequencies that fall within specific bands. Each of the input ports carries signals that fall within different frequency bands. This presents a challenge for the LNA which is then required to achieve its performance targets across a frequency band. The LNA is typically optimised for performance at a frequency close to the centre of its band of operation. Performance degrades as the LNA is required to operate at frequencies that deviate from the frequency of optimal performance. Where the frequency range over which the LNA is required to operate is large, e.g. 1.8 GHz to 2.7 GHz, performance can deteriorate to such a degree over the band to the extent that the system requirements cannot be met at over entire frequency band.

There is therefore a need to provide RF switching circuit that addresses at least some of the drawbacks of the prior art.

### SUMMARY

These and other problems are addressed by providing an RF Switching having an RF switch operable with a Low Noise Amplifier (LNA) that is optimised for performance across multiple frequency bands.

The present disclosure relates to an RF switching circuit which comprises an RF switch having multiple RF inputs and two or more switch outputs; a low noise amplifier (LNA) having two or more amplification branches, each amplification branch being associated with a corresponding switch output; and a bypass switching mechanism configured for selectively bypassing the amplification branches.

In one aspect, the RF switching circuit further comprises two or more input matching networks; each input matching network being associated with a corresponding amplification branch.

In another aspect, the bypass switching mechanism is configured for selectively bypassing the respective input matching networks.

In a further aspect, each input matching network is operably coupled between a corresponding one of the switch outputs and a corresponding one of the amplification branches.

In one aspect, the bypass switching mechanism comprises one or more bypass switches.

In another aspect, each amplification branch is associated with a corresponding bypass switch.

In an exemplary arrangement, each bypass switch is operably coupled between a corresponding one of the switch outputs and an output of the LNA.

In one aspect, each amplification branch is optimised for a corresponding frequency band.

In another aspect, each input matching network is optimised for a corresponding frequency band.

In one exemplary aspect, each amplification branch is optimised for a predetermined cellular frequency band. Advantageously, one of the amplification branches is optimised for a first frequency band and another one of the amplification branched is optimised for a second frequency band. Preferably, the first frequency band and the second frequency bands have different frequency ranges. In one example, the first frequency band is a mid-band frequency cellular range and the second frequency band is a high-band frequency cellular range. In another example, the first frequency band has a frequency range of 1.8 GHz to 2.3 GHz; and the second frequency band has a frequency range of 2.3 GHz to 2.7 GHz.

In one aspect, each amplification branch comprises an input DC blocking capacitor.

In another aspect, each input DC blocking capacitor is operably coupled to a gate of a first transistor.

In a further aspect, a first DC bias voltage source is operably coupled to the gate of the first transistor via a resisitive load.

In another aspect, a cascode transistor is operably coupled to the first transistor which together form an amplification stage.

In one aspect, a second DC bias voltage source is operably coupled to the gate of the cascode transistor.

In one exemplary embodiment, the cascode transistor is operably coupled to an inductor.

In another aspect, an output DC blocking capacitor is operably coupled to the two or more amplification branches and an output of the LNA.

In one aspect, each amplification branch comprises an input shunt switch operably coupled to the input DC blocking capacitor and ground.

In another aspect, each input shunt switch provides an ESD discharge path to ground for an ESD event occurring on the corresponding amplification branch.

In a further aspect, each input shunt switch provides signal attenuation.

In an exemplary aspect, the input shunt switch is open when the corresponding amplification branch is active.

In one example, the RF switch is a multi-pole multi-throw switch. In another example, the RF switch is a single-pole multi-throw switch.

In another aspect, the LNA has multiple inputs and a single output.

In one aspect, the poles of the RF switch are coupled to inputs of LNA.

In a further aspect, the bypass switching mechanism is configured to selectively connect a predetermined pole of the RF switch to the output of LNA.

In another aspect, the low noise amplifier has a Noise Figure of less than 1 dB. In one exemplary arrangement, the low noise amplifier has a Noise Figure of less than 2 dB.

In a further aspect, the low noise amplifier is configured to provide a gain of between 10 dB and 20 dB within its frequency range of operation.

The present disclosure also relates to a semiconductor substrate having an RF switching circuit fabricated thereon, wherein the RF switching circuit comprises an RF switch having multiple RF inputs and two or more switch outputs; a low noise amplifier (LNA) having two or more amplification branches, each amplification branch being associated with a corresponding switch output; and a bypass switching mechanism configured for selectively bypassing the amplification branches.

Additionally, the present disclosure relates to a method of fabricating an RF switching circuit, the method comprising providing an RF switch on a substrate having multiple RF inputs and two or more switch outputs; providing a low noise amplifier (LNA) on the substrate having two or more amplification branches, each amplification branch being associated with a corresponding switch output; and providing a bypass switching mechanism on the substrate configured for selectively bypassing the amplification branches.

The present disclosure further relates to a low noise amplifier comprising one or more amplification branches, each amplification branch being associated with a corresponding RF switch output and a corresponding input matching network; wherein each amplification branch and the corresponding input matching network are optimised for a corresponding frequency band; and optionally, further comprising a bypass switching mechanism configured for selectively bypassing the amplification branches and the corresponding input matching network.

Additionally, the present teaching relates to an RF switching circuit comprising a low noise amplifier (LNA) having one or more amplification branches, each amplification branch being associated with a corresponding RF switch output and a corresponding input matching network; and a bypass switching mechanism configured for selectively bypassing the respective amplification branches and the corresponding input matching network.

These and other features will be better understood with reference to the following Figures which are provided to assist in an understanding of the present teaching.

### BRIEF DESCRIPTION OF THE DRAWINGS

FIG. 1 is a circuit diagram of a prior art RF switch.

FIG. 2 is a block diagram of a prior art RF switch.

FIG. 3 is pin out diagram of a prior art RF switch.

FIG. 4 is a schematic circuit diagram of a detail of the RF switch of FIG. 2.

FIG. 5 is a schematic circuit diagram of a detail of the RF switch of FIG. 2.

FIG. 6 is a schematic circuit diagram of a detail of the RF switch of FIG. 2.

FIG. 7 is a schematic circuit diagram of a detail of the RF switch of FIG. 2.

FIG. 8 is a schematic circuit diagram of a detail of the RF switch of FIG. 2.

FIG. 9 is a schematic circuit diagram of a detail of the RF switch of FIG. 2.

FIG. 10 is an equivalent circuit of the RF isolation filters of FIG. 8.

FIG. 11 is a cross sectional side view of a prior art silicon-on-insulator structure on which the RF switch of FIG. 2 may be fabricated thereon.

FIG. 12 is a circuit diagram of an exemplary RF switching circuit which is provided merely to illustrate drawbacks associated with a low noise amplifier that is optimised for a single frequency band.

FIG. 13 is a circuit diagram of an exemplary RF switch circuit in accordance with the present teaching.

FIG. 14 is a schematic diagram of a detail of the RF switching circuit of FIG. 13.

FIG. 15 is a schematic diagram of a detail of the RF switching circuit of FIG. 13.

FIG. 16 is an expanded view of the RF switching circuit of FIG. 15.

### DETAILED DESCRIPTION OF THE DRAWINGS

The present teaching will now be described with reference to some exemplary RF switching circuits. It will be understood that the exemplary RF switching circuit are provided to assist in an understanding of the present teaching and are not to be construed as limiting in any fashion. Furthermore, circuit elements or components that are described with reference to any one Figure may be interchanged with those of other Figures or other equivalent circuit elements without departing from the spirit of the present teaching.

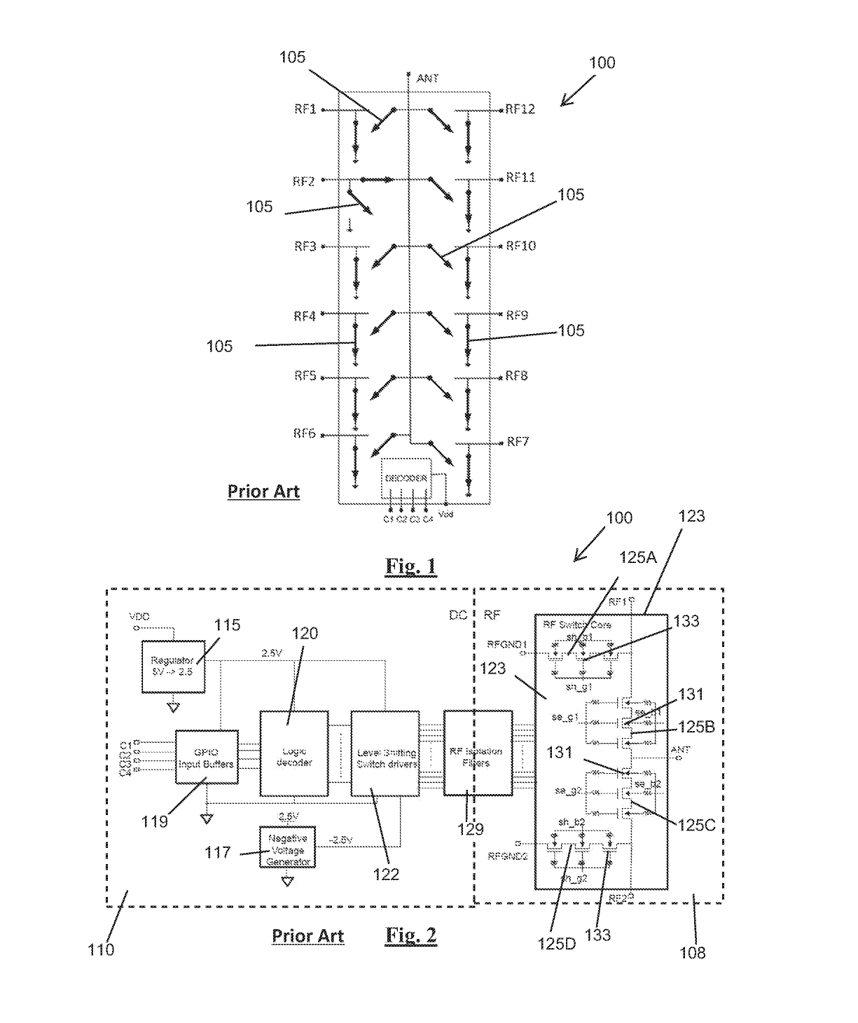

In advance of describing a radio frequency (RF) switching circuit in accordance with the present teaching an exemplary prior art RF switch 100 is first described with reference to FIGS. 1 to 11. The circuit elements described with reference to the RF switch 100 provide the basic circuit blocks of a traditional RF switch. The RF switch 100 comprises a plurality of switching elements 105 which are operably configured to control the flow of RF power signals between circuit nodes. The RF switch 100 includes two domains; namely, an RF domain section 108 and a direct current (DC) domain section 110 as illustrated in FIG. 2. The DC domain section 110 may comprise one or more digital logic, bias generation, filter, memory, interface, driver and power management circuitry. In the exemplary RF switch 100 the DC domain consists of 5V to 2.5V regulator 115, a negative voltage generator 117, input buffers 119, logic decoder 120 and level-shifting switch drivers 122. These circuits are operably configured to generate the required bias levels, provide power management support and control selection of active switch path through which RF power flows depending on the values set on the control pins C1-C4. Such RF switches are well known in the art.

The RF domain section 108 comprises a switch core 123 which in the exemplary arrangement includes two series-shunt switch elements 125A-125D. A plurality of transistors 131, 133 are stacked in the switch elements 125A-125D to divide the RF voltage evenly across the transistors so that the voltage between any two terminals of the individual transistors during operation do not exceed a level that may cause performance degradation or damage to the device. RF isolation filters 129 are placed on signal lines controlling the switch gate and body terminals of the transistors 131,133 at the boundary between the RF domain section 108 and the DC domain section 110. In the exemplary arrangement, the RF switch 100 is provided as single-pole, twelve throw (SP12T) RF switch having input/out pins 127 as illustrated in FIG. 3. A description of the pins 127 is detailed in table 1 below.

TABLE 1

| Pin Name | Description |
|---|---|
| RF1 | RF Port |
| RFGND1 | RF Ground reference for shunt |
| | transistor connecting to RF1 & RF2 |
| | Ports |
| RF2 | RF Port |
| RF3 | RF Port |
| RFGND2 | RF Ground reference for shunt |
| | transistor connecting to RF3 & RF4 |
| | Ports |
| RF4 | RF Port |
| RF5 | RF Port |
| RFGND3 | RF Ground reference for shunt |
| | transistor connecting to RF5 & RF6 |
| RF6 | RF Port |
| GND | Ground reference for DC domain |
| C1 | Control input, C1-C4 decoded to |
| | select which of RF1-RF12 to ANT |
| | paths is active |
| C2 | Control input, C1-C4 decoded to |
| | select which of RF1-RF12 to ANT |
| | paths is active |
| C3 | Control input, C1-C4 decoded to |
| | select which of RF1-RF12 to ANT |
| | paths is active |
| C4 | Control input, C1-C4 decoded to |
| | select which of RF1-RF12 to ANT |
| | paths is active |
| VDD | Supply Voltage for DC domain |
| RF7 | RF Port |
| RFGND4 | RF Ground reference for shunt |
| | transistor connecting to RF7 & RF8 |
| RF8 | RF Port |
| RF9 | RF Port |
| RFGND5 | RF Ground reference for shunt |
| | transistor connecting to RF9 & RF10 |
| RF10 | RF Port |
| RF11 | RF Port |
| RFGND6 | RF Ground reference for shunt |
| | transistor connecting to RF11 & |
| | RF12 |
| RF12 | RF Port |
| ANT | Antenna Port, RF Common Port |

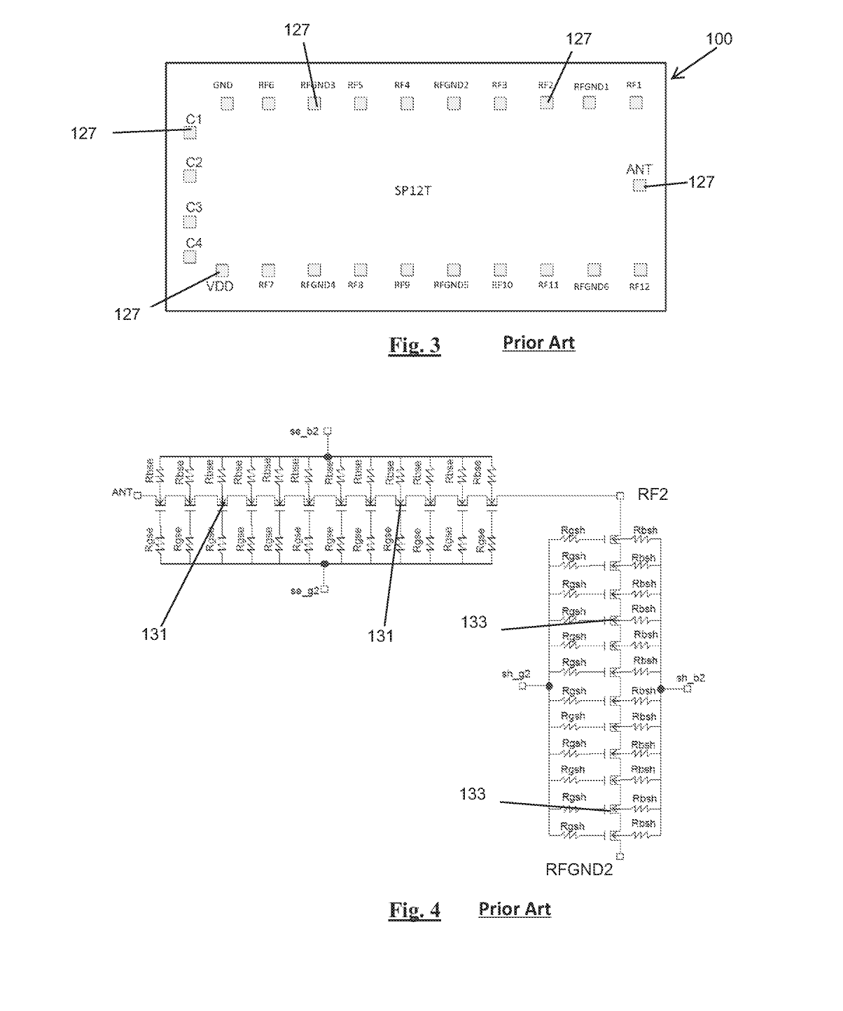

FIG. 4 shows more detail of the switch core 123 of FIG. 2. The switch core 123 includes a plurality of series transistor elements 131 and a plurality of shunt transistor elements 133. The series transistor elements 131 are in a stacked configuration operably coupled between the antenna node ANT and the RF2 node. The shunt transistor elements 133 are in a stacked configuration operably coupled between the RF2 node and RFGND2 node. The number of transistors in a stack is determined by the maximum RF voltage level that can be experienced on the RF nodes when the switch is operational. A stack of 10-13 transistor devices is common for maximum RF voltages that can be experienced at GSM transmit power levels.

The voltage regulator 115 of the switch 100 is illustrated in more detail in FIG. 5. The voltage regulator 115 comprises a bandgap reference 140 operably coupled to an input terminal of an op-amp 141. A pair of mosfet transistors MP7, MP8 and a pair of resistors Rfb1, Rfb2 are stacked between a VDD node and a ground reference node. The output from the op-amp 141 drives the MP7 transistor. The gate of the MP8 transistor is operably coupled to a reference voltage source vcascode. A feedback loop is provided from a node intermediate Rfb1 and Rfb2 and an input terminal to the op-amp 141. The voltage regulator 115 is configured to provide a regulated voltage level at a node Vdd2p5. In the exemplary arrange the voltage at the node vdd2p5 is +2.5V.

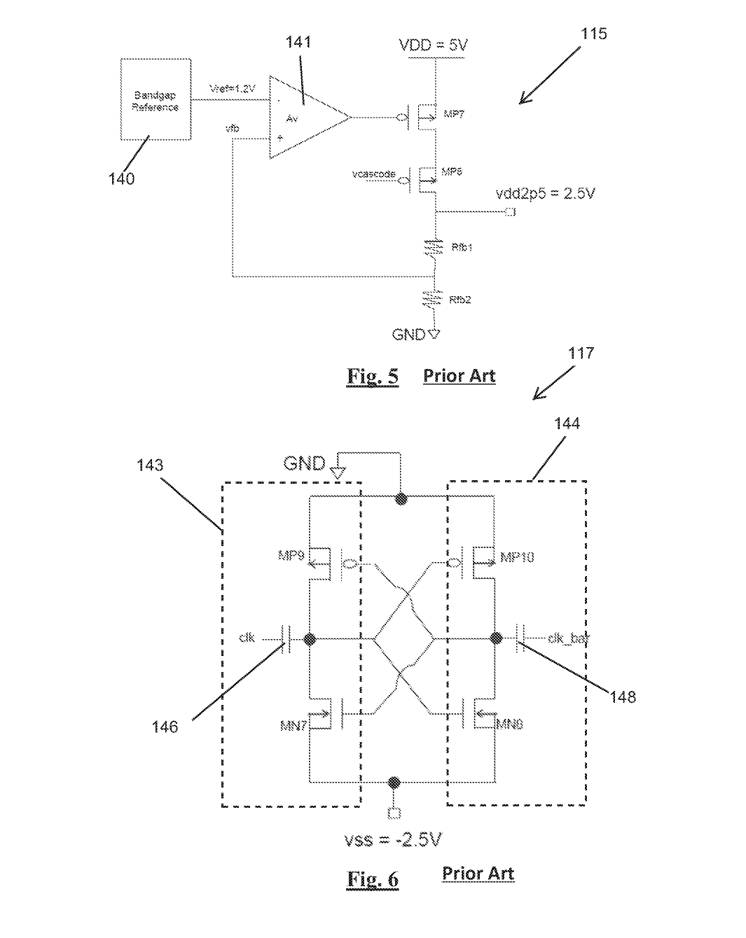

The negative voltage generator 117 of the switch 100 is illustrated in more detail in FIG. 6. The negative voltage generator 117 comprises a first segment 143 and a second segment 144. The first and second segments 143, 144 are operably coupled between a ground reference node GND and a vss node. The first segment 143 comprises a PMOS transistor MP9 stacked on an NMOS transistor MN7. A first capacitor 146 which receives a clock signal clk is coupled intermediate MP9 and MN7. The second segment 144 comprises a PMOS transistor MP10 stacked on an NMOS transistor MN8. A second capacitor 148 which receives an inverse clock signal clk_bar is coupled intermediate MP10 and MN8. The gates of MP9 and MN7 are driven by the inverse clock signal clk_bar. The gates of MP10 and MN8 are driven by the clock signal clk. The negative voltage generator 117 is configured to provide a negative voltage at the node vss. In the exemplary arrangement the negative voltage which is provided at node vss is 2.5V.

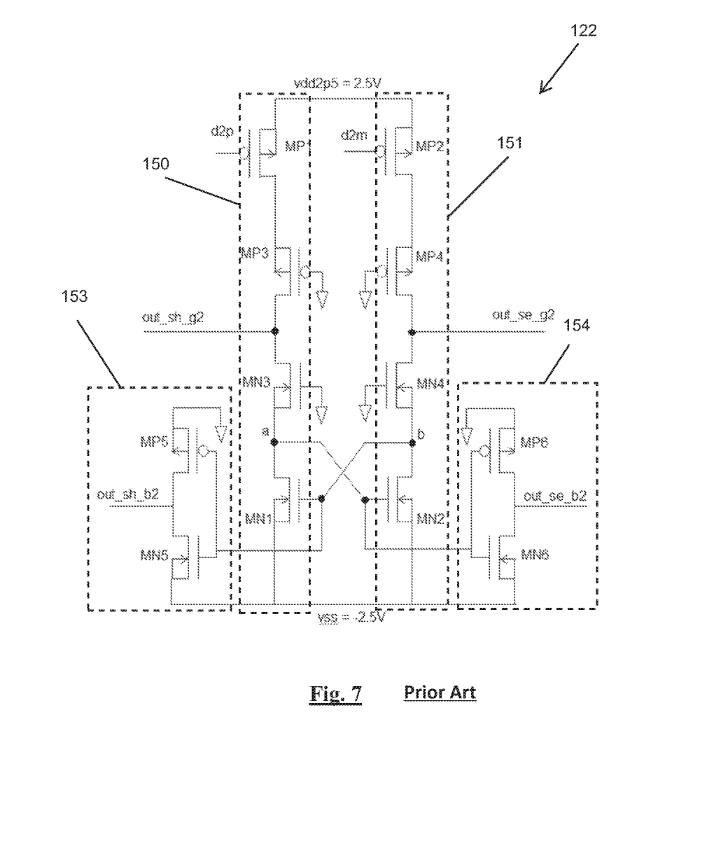

The level shifting switch driver 122 of the switch 100 is illustrated in more detail in FIG. 7. The switch driver 122 comprises a first switch segment 150 and a second switch segment 151, which are operably coupled between the vdd2p5 node of the 5V-2.5V regulator 115 and the negative voltage node vss of the negative voltage generator 117. In the exemplary arrangement, the first switch segment 150 comprises a pair of PMOS transistors MP1 and MP3 and a pair of NMOS transistors MN3 and MN1. The second switch segment 151 comprises a pair of PMOS transistors MP2 and MP4 and a pair of NMOS transistors MN4 and MN2. The first switch segment 150 is associated with a first CMOS inverter 153 that includes a PMOS transistor MP5 and an NMOS transistor MN5 operably coupled between the vss node and a ground node. The second switch segment 151 is associated with a second CMOS inverter 154 that includes a PMOS transistor MP6 and an NMOS transistor MN6 operably coupled between the vss node and a ground node. The level shifting switch driver 122 is configured to provide four output drive signals which are outputted at nodes out_sh_g2, out_sh_b2, out_se_g2 and out_se_b2. These drive signals are then filtered by the RF isolation filters 129 and the filtered versions of the signals are used to drive the series-shunt switch elements 125A-125D in the switch core 123 of the RF section 108.

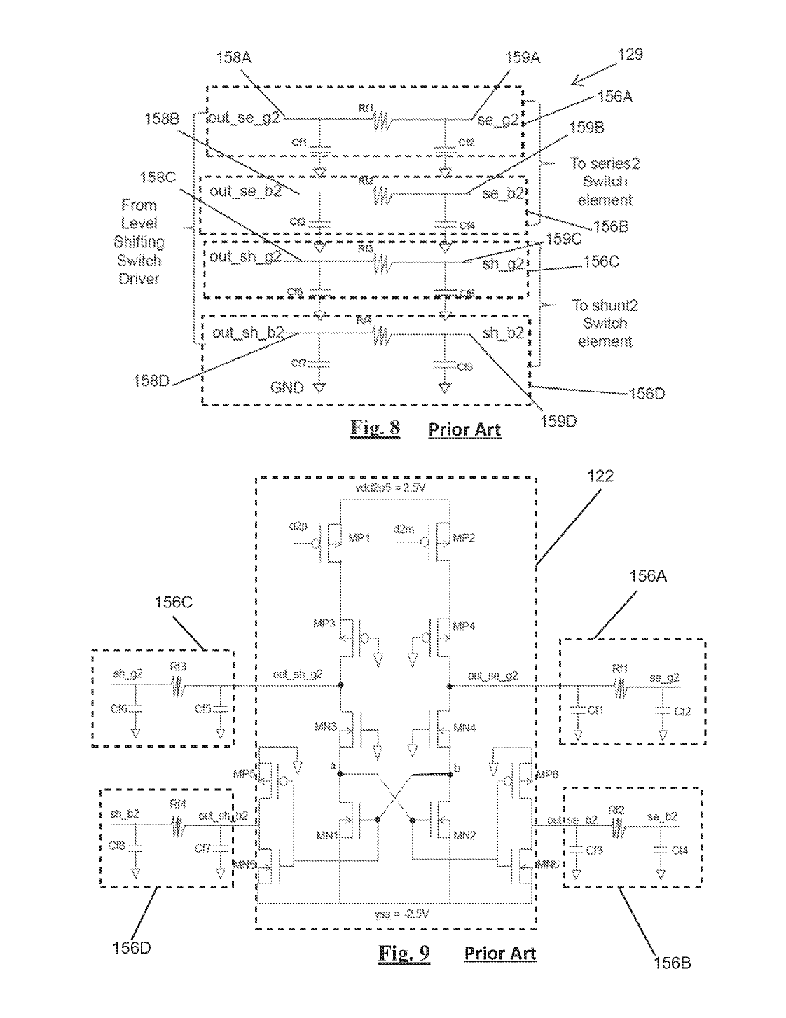

The RF isolation filters 129 of the switch 100 are illustrated in more detail in FIG. 8. The RF isolation filters 129 are provided in an interface section operably between the DC domain section 110 and the RF domain section 108. In the exemplary arrangement, four filter segments 156A-156D are provided. For brevity, only the filter segment 156A is described. However, it will be appreciated by those of ordinary skill in the art that each of the filter segments 156B to 156D operates in a similar fashion to the filter segment 156A. The filter segment 156A includes a pair of capacitors Cf1 and Cf2 with a resistor Rf1 operably coupled there between. An input node 158A and an output node 159A are provided at respective opposite ends of the resistor Rf1. The capacitors Cf1 and Cf2 each have a first terminal coupled to a ground node. The second terminal of the capacitor Cf1 is coupled to the input node 158A, and the second terminal of the capacitor Cf2 is coupled the output node 159A. The input node 158A receives a drive signal from the node out_se_g2 of the level shifting switch drivers 122 and the output node 159 provides a filtered signal from the node se_g2 which drives the gate terminals of the series switch element 125C in the RF switch core 123 of FIG. 2. Thus the signal from node se_g2 is a filtered representation of the signal from node out_se_g2. In the exemplary arrangement, the filter segment 156B outputs a filtered signal from the node se_b2 which is derived from the signal from node out_se_b2. The filtered signal from the node se_b2 is used to drive the body terminals of the series switch element 125C in the RF switch core 123. The filter segment 156C outputs a filtered signal from node sh_g2 that is derived from the signal of node out_sh_g2. The filtered signal from the node sh_g2 drives the gate terminals of the shunt switch element 125D in the RF switch core 123. The filter segment 156D outputs a filtered signal from the node sh_b2 which is derived from the signal of node out_sh_b2. The filtered signal from the node sh_b2 drives the body terminals of the shunt switch element 125D in the RF switch core 123.

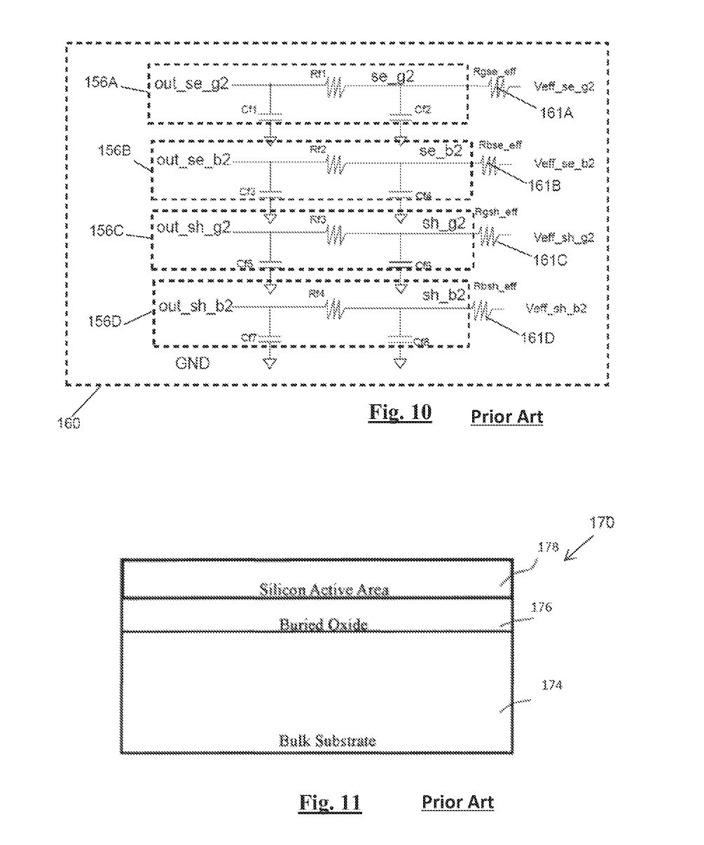

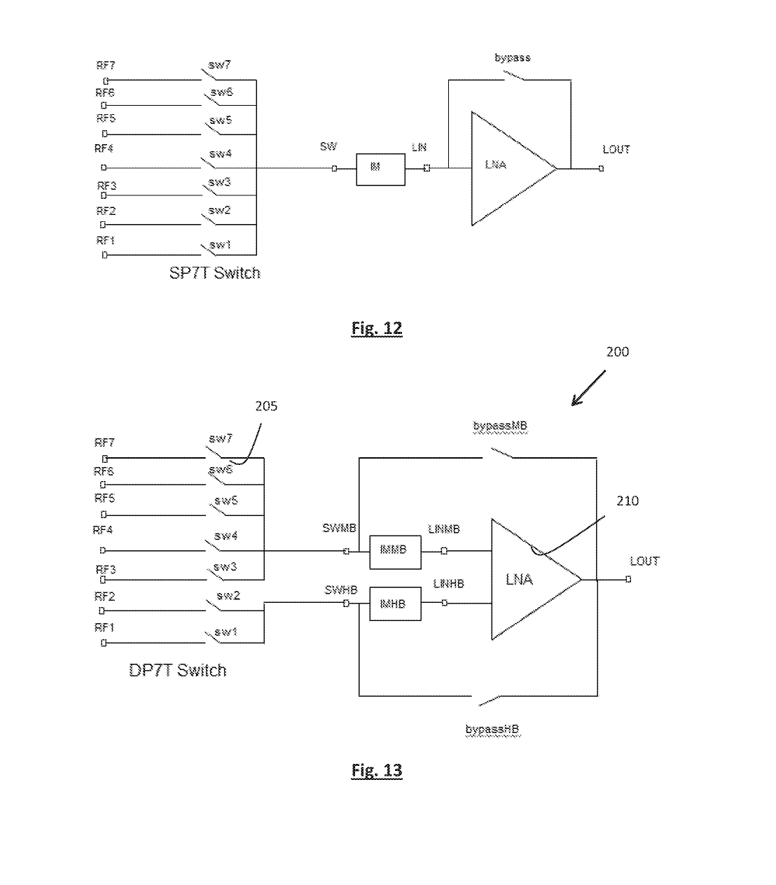

FIG. 9 illustrates the RF isolation filters 156A-156D operably coupled to the output nodes of the level shifting switch drivers 122. The schematic of FIG. 9 combines the circuit diagrams of FIGS. 7 and 8. An equivalent circuit 160 of the interface between the DC domain section 110 and the RF domain section 108 is illustrated in FIG. 10. The circuit 160 is substantially similar to the circuit of FIG. 8 and like components are indicated by similar reference numerals. An additional resistor element 161 is provided on each filter segment 156 which represents the effective resistance connecting to the gate and body terminals of the transistor elements 131, 133 in the RF switch core 123 of FIG. 2.

Referring now to FIG. 11 which illustrates a typical silicon-on-insulator (SOI) structure 170 on which the RF switch 100 may be fabricated thereon. In the exemplary arrangement, an insulating layer sits on top of a silicon substrate. A typical material for the insulating layer is silicon dioxide. In general SOI technologies consist of a bulk substrate 174, a buried oxide layer 176 and a thin active silicon layer 178. The bulk substrate 174 is generally a high resistivity substrate. The bulk substrate 174 can be either P-type or N-Type. A typical thickness for the bulk substrate is 250 μm. The buried oxide layer 176 is an insulator layer, typically silicon dioxide. A typical thickness of the buried oxide layer 176 is 1 μm. The active silicon layer 178 above the buried oxide layer 176 is typically of the order of 0.2 μm. The RF switch 100 may be fabricated in the silicon active area 178 using semiconductor processing techniques that are well known in the art and may include for example, but not limited to, deposition, implantation, diffusion, patterning, doping, and etching. The RF domain section 108 and the DC domain section 110 of the RF switch 100 are typically fabricated on a single semiconductor structure.

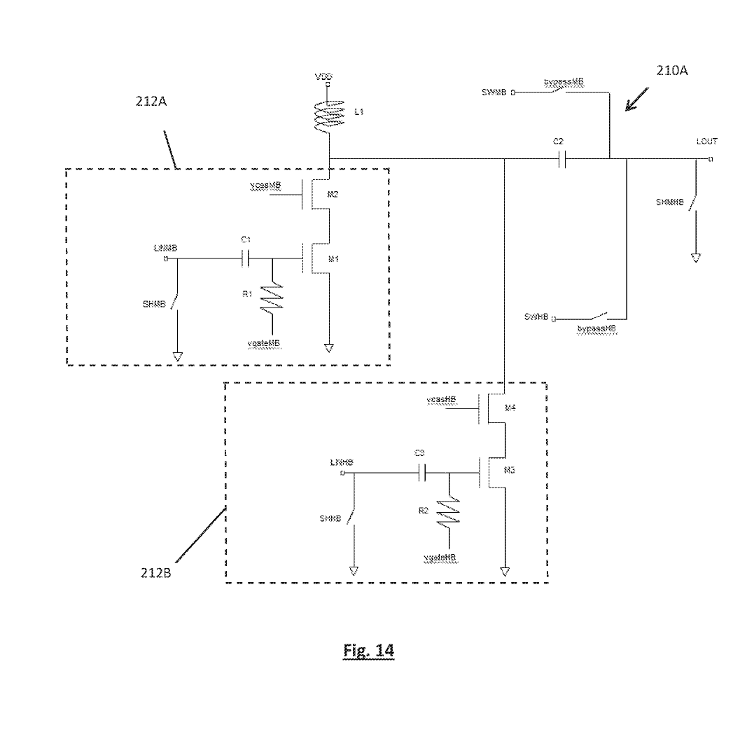

FIG. 12 shows an exemplary RF switching circuit which is merely provided to illustrate the drawbacks associated with a low noise amplifier (LNA) having a single amplification path. The circuit includes a single pole, seven throw, SP7T, RF switch to selectively control the flow of RF power from receive ports, RF1-RF7, through the LNA to a common port at the output of LNA. The SP7T switch includes seven switch paths, sw1-sw7, that can be selectively enabled to allow RF power to flow from each of the switch input ports, RF1-RF7, to the switch common port, SW. The switch common port SW is connected to an input matching network, IM. Output from the input matching network is connected to input of the LNA, LIN. The input matching network IM may include an inductor or other frequency dependent elements. The LNA includes a bypass switch, bypass, positioned between its input port, LIN, and its output port, LOUT. When a signal at a selected input port is weak the bypass switch is open and the LNA is set to a high gain configuration. When the signal at a selected input port is large the bypass switch is closed and the LNA is set to a low gain configuration. Typically each switch path is allocated to a specific frequency range of operation within the overall frequency band. Each of the input ports carries signals that fall within different frequency bands. This presents challenges for the LNA which is then required to achieve its performance targets across a frequency band. The LNA is typically optimised for performance at a frequency close to centre of its band of operation. Performance degrades as the LNA is required to operate at frequencies that deviate from the frequency of optimal performance. Where the frequency range over which the LNA is required to operate is large, e.g. 1.8 GHz to 2.7 GHz, performance can deteriorate to such a degree over the band to the extent that the system requirements cannot be met at over entire frequency band.

FIG. 13 shows an exemplary RF switching circuit 200 in accordance with the present teaching which addresses the drawsbacks outlined with reference to FIG. 12. In this exemplary circuit, ports RF1-RF2, are allocated to operate in the 2.3-2.7 GHz frequency range, while ports RF3-RF7 are allocated to operate in the 1.8-2.3 GHz frequency range. It will be appreciated that it is not intended to limit the present teaching to these exemplary frequency bands which are provided by way of example only. For convenience, in the following discussion the frequency range 2.3-2.7 GHz will be referred to as High Band, HB, and the frequency range 1.8-2.3 GHz will be referred to as the Mid Band, MB. The frequency bands described herein may include cellular frequency bands set by the 3^{rd} Generation Partnership Project, 3GPP consortium for cellular systems.

The circuit 200 includes a dual pole, seven throw, DP7T, RF switch 205 arranged to selectively control the flow of RF power from the receive ports, RF1-RF7, through a low noise amplifier (LNA) 210 to a common port at the output of the LNA 210. The DP7T RF switch 205 includes five switch paths, sw3-sw7, that can be selectively enabled to allow RF power to flow from each of the switch input ports, RF3-RF7, to a mid-band switch pole, SWMB. The mid-band switch pole, SWMB, is connected to a mid-band input matching network, IMMB. The IMMB may include an inductor or other frequency dependent elements. Output from the mid-band input matching network is connected to a mid-band input of the LNA, LINMB. The LNA 210 includes a mid-band bypass switch, bypassMB, positioned between the mid-band switch pole, SWMB, and the output port, LOUT. When a signal at a selected mid-band input port is weak the mid-band bypass switch is opened and the LNA 210 is set to a high gain configuration. When a signal at a selected mid-band input port is large the mid-band bypass switch is closed and the LNA 210 is set to a low gain configuration.

The DP7T switch 205 includes two switch paths, sw1-sw2, that can be selectively enabled to allow RF power to flow from each of the switch input ports, RF1-RF2, to a high-band switch pole, SWHB. The high-band switch pole, SWHB, is connected to a high-band input matching network, IMHB. The IMHB may include an inductor or other frequency dependent elements. Output from the high-band input matching network is connected to a high-band input of the LNA, LINHB. The LNA 210 includes a high-band bypass switch, bypassHB, positioned between the high-band switch pole, SWHB, and the output port, LOUT. When a signal at a selected high-band input port is weak the high-band bypass switch is opened and the LNA 210 is set to a high gain configuration. When a signal at a selected high-band input port is large the high-band bypass switch is closed and the LNA 210 is set to low gain configuration.

Typically each switch path is allocated to specific frequency range of operation within overall frequency band. FIG. 14 shows schematic detail of an exemplary LNA 210A which may provide the LNA in FIG. 2, for example. The LNA 210A in the exemplary embodiment includes two amplification branches 212A and 212B, however, it is not intended to limit the present teaching to two amplification branches as additional amplification branches 210 may be provided if desired. In the amplification branch 212 A, the mid-band LNA input, LINMB, is connected to one terminal of a DC blocking capacitor, C1. The other terminal of the DC blocking capacitor, C1, is connected to a gate terminal of a transistor M1. A DC bias voltage source, vgateMB, is provided to a gate terminal of the transistor M1 through a resistor R1. A source terminal of transistor M1 is connected to GND while a drain terminal of the transistor M1 is connected to a source terminal of a cascode transistor M2. A DC bias level of vcasMB is provided at a gate terminal of the transistor M2. The drain terminal of the cascode transistor M2 is connected to one terminal of a inductor L1. The other terminal of the inductor, L1, is connected to a LNA VDD terminal which supplies current required by the LNA 210A and also provides a DC bias voltage at the drain of the transistor M2. The drain terminal of M2 is also connected to one terminal of an output DC blocking capacitor C2. The other terminal of the DC blocking capacitor C2 is connected to output port, LOUT.

The mid-band bypass switch, bypassMB, is connected between the SWMB input port and the output port, LOUT. The mid-band bypass switch, bypassMB, is closed when one of the mid-band switch paths, sw3-sw7, is selected to be active and the LNA 210A is set to low gain configuration because the signal at a selected mid-band input port does not require gain.

A mid-band shunt switch, SHMB, is connected between the mid-band LNA input, LINMB and ground. The mid-band shunt switch is opened when the bias voltage, vgateMB, is set so that the amplifier stage M1, M2 provides gain between LINMB and LOUT or when the bias voltage, vgateHB, is set so that the amplifier stage M3, M4 provides gain between LINHB and LOUT.

In an exemplary embodiment, the mid-band shunt switch may provide an ESD discharge path to ground for an ESD event occurring on the mid-band LNA input. The mid-band shunt switch may also provide attenuation in conjunction with the mid-band bypass switch, bypassMB, and the output shunt switch, SHMHB, when one of the mid-band switch paths, sw3-sw7, is selected to be active and the LNA 210A is set to a low gain configuration because a signal at a selected mid-band input port does not require gain. The mid-band shunt switch may also contribute to the mid-band input network when one of the mid-band switch paths, sw3-sw7, is selected to be active and the LNA 210A is set to provide gain between LINMB and LOUT.

In the amplification branch 212B the high-band LNA input, LINHB, is connected to one terminal of a DC blocking capacitor, C3. The other terminal of the DC blocking capacitor, C3, is connected to a gate terminal of transistor M3. A DC bias voltage, vgateHB, is provided to a gate terminal of transistor M3 through resistor R2. A source terminal of the transistor M3 is connected to GND while a drain terminal of a transistor M3 is connected to a source terminal of a cascode transistor M4. The DC bias level of vcasHB is provided at a gate terminal of the transistor M4. A drain of the transistor M4 is connected to one terminal of the inductor L1. The other terminal of the inductor, L1, is connected to a LNA VDD terminal which supplies current required by the LNA 210A and also provides a DC bias voltage at the drain of transistor M4. The drain of the transistor M4 is also connected to one terminal of an output DC blocking capacitor C2. The other terminal of the output DC blocking capacitor C2 is connected to the output port, LOUT. The drain terminal of transistor M2 may also be connected to the drain terminal of transistor M4.

The high-band bypass switch, bypassHB, is connected between the SWHB input port and the output port, LOUT. The high-band bypass switch, bypassHB, is closed when one of the high-band switch paths, sw1-sw2, is selected to be active and the LNA 210A is set to a low gain configuration because a signal at a selected high-band input port does not require gain.

A high-band shunt switch, SHHB, is connected between the high-band LNA input, LINHB and ground. The high-band shunt switch is open when bias voltage, vgateHB, is set so that amplifier stage M3, M4 provides a gain between LINHB and LOUT or when the bias voltage, vgateMB, is set so that the amplifier stage M1, M2 provides a gain between LINMB and LOUT.

In an exemplary arrangement, the high-band shunt switch may provide an ESD discharge path to ground for an ESD event occurring on the high-band LNA input. The high-band shunt switch may also provide attenuation in conjunction with the high-band bypass switch, bypassHB, and the output shunt switch, SHMHB, when one of the high-band switch paths, sw1-sw2, is selected to be active and the LNA 210A is set to a low gain configuration because a signal at a selected high-band input port does not require gain. The high-band shunt switch may also contribute to the high-band input network when one of the high-band switch paths, sw1-sw2, is selected to be active and LNA is set to provide gain between LINHB and LOUT.

Output shunt switch SHMHB is connected between output port, LOUT, and ground. Output shunt switch is open when bias voltage, vgateHB, is set so that the amplifier stage M3, M4 provides gain between LINHB and LOUT or when bias voltage, vgateMB, is set so that amplifier stage M1, M2 provides gain between LINMB and LOUT. Output shunt switch provides ESD discharge path to ground for ESD event on output port LOUT.

The output shunt switch may also provide attenuation in conjunction with the high-band bypass switch, bypassHB, and the high-band shunt switch, SHHB, when one of the high-band switch paths, sw1-sw2, is selected to be active and the LNA 210A is set to a low gain configuration because a signal at a selected high-band input port does not require gain. The output shunt switch may also provide attenuation in conjunction with the mid-band bypass switch, bypassMB, and the mid-band shunt switch, SHMB, when one of the mid-band switch paths, sw3-sw7, is selected to be active and the LNA 210A is set to a low gain configuration because signal at a selected mid-band input port does not require gain. The output shunt switch may also contribute to the high-band and mid-band output networks when one of the switch paths, sw1-sw7, is selected to be active and the LNA 210A is set to provide gain between LINHB or LINMB and LOUT.

Exemplary arrangements of each switch and bias setting is shown in table 2 below.

TABLE 2
Truth Table for Switch and Bias Settings

| Selected | Active | | | | | | | | |
|---|---|---|---|---|---|---|---|---|---|
| Input | DP7T | LNA | | | | | | | |
| Port | switch | Gain | SHMB | bypassMB | vgateMB | SHMHB | SHHB | bypassHB | vgateHB |
| RX1 | se1 | Low | ON | OFF | 0 V | ON | ON | ON | 0 V |
| RX2 | se2 | Low | ON | OFF | 0 V | ON | ON | ON | 0 V |
| RX3 | se3 | Low | ON | ON | 0 V | ON | ON | OFF | 0 V |
| RX4 | se4 | Low | ON | ON | 0 V | ON | ON | OFF | 0 V |
| RX5 | se5 | Low | ON | ON | 0 V | ON | ON | OFF | 0 V |
| RX6 | se6 | Low | ON | ON | 0 V | ON | ON | OFF | 0 V |
| RX7 | se7 | Low | ON | ON | 0 V | ON | ON | OFF | 0 V |
| RX1 | se1 | High | OFF | OFF | 0 V | OFF | OFF | OFF | VON |
| RX2 | se2 | High | OFF | OFF | 0 V | OFF | OFF | OFF | VON |
| RX3 | se3 | High | OFF | OFF | VON | OFF | OFF | OFF | 0 V |
| RX4 | se4 | High | OFF | OFF | VON | OFF | OFF | OFF | 0 V |
| RX5 | se5 | High | OFF | OFF | VON | OFF | OFF | OFF | 0 V |
| RX6 | se6 | High | OFF | OFF | VON | OFF | OFF | OFF | 0 V |
| RX7 | se7 | High | OFF | OFF | VON | OFF | OFF | OFF | 0 V |

Exemplary values for the LNA Gain settings are approximately 15 dB for high and approximately −2 dB for low. VON values for vgateHB and vgateMB are typically some value in excess of the threshold voltage for the transistors M1 and M3 so that sufficient current flows through the amplifier stages to achieve the required noise figure and gain at the frequency of operation. Bias voltages vgateHB and vgateMB are set to 0V in order to keeps transistors M1 and M3 off so that only leakage current flows through amplifier stages. It will be appreciated that it is not intended to limit the present teaching to these exemplary value which are provided by way of example only

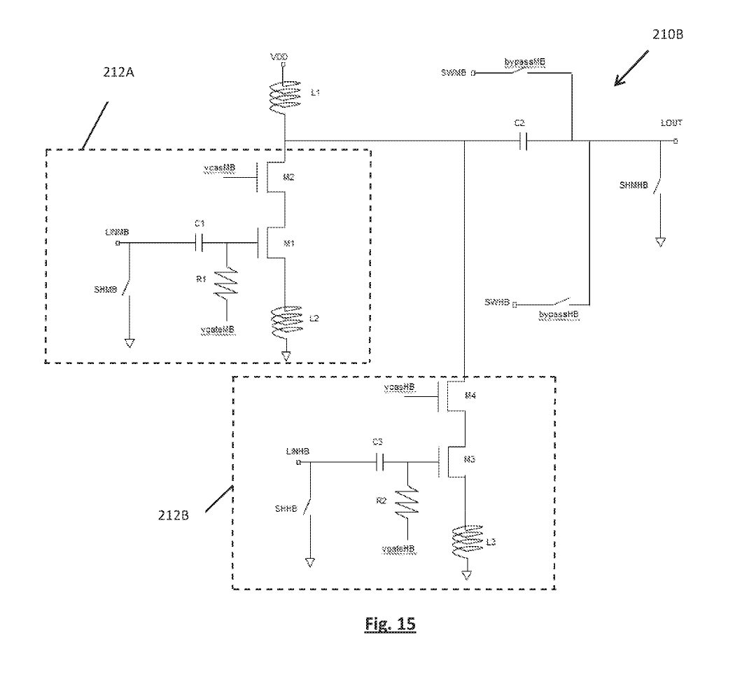

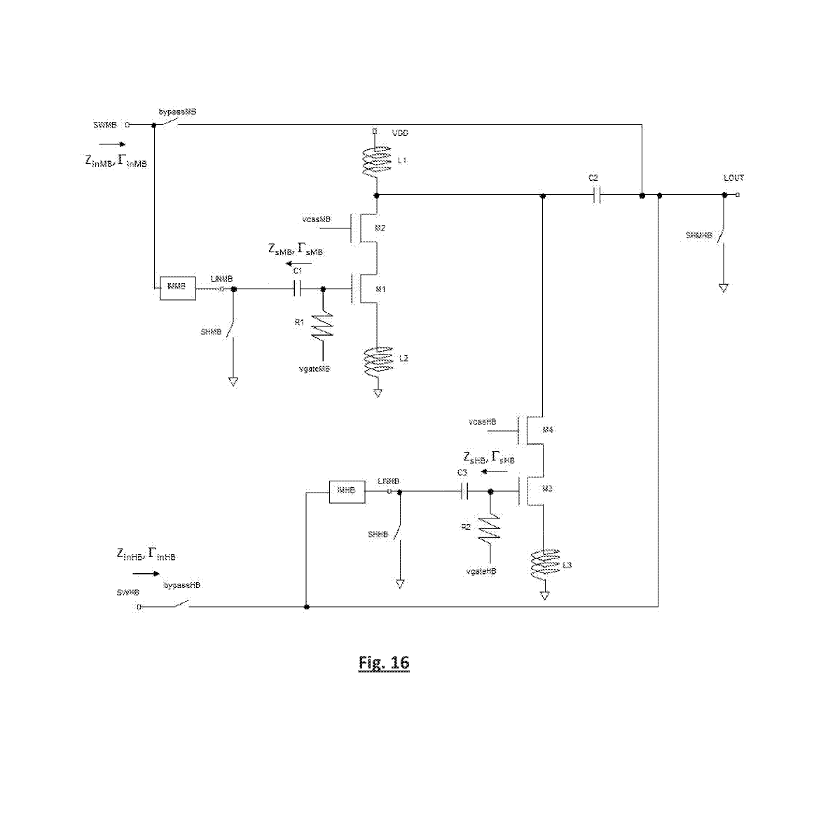

FIG. 15 shows schematic detail of an exemplary LNA 210B which may provide the LNA in FIG. 2. The LNA 210B is substantially similar to the LNA 210A of FIG. 14 and like components are indicated by similar reference labels. The main difference is that LNA 210B includes degeneration inductors L2 and L3. Otherwise the operation of the LNA 210B is substantially similar to that of the LNA 210A. The degeneration inductor, L2, is provided in the amplification branch 212A between the source of transistor M1 and ground. The degeneration inductor, L3, is provided in the amplification branch 212B between source of transistor M3 and ground. The addition of the degeneration inductors may improve noise figure, gain, linearity, return loss, stability or other parameters at desired frequency of operation. One of the many advantages of using a dual-input LNA in accordance with the present teaching is that it allows the inductor value to be selected for optimal performance over the sub-ranges of frequencies that is covered by each of the mid-band paths and high-band paths than would not be possible if a single input LNA such as that illustrated in FIG. 12 was used covering the full range of mid-band and high-band paths.

FIG. 16 is an expanded view of the circuit level diagram of FIG. 15 and block level diagram of FIG. 13 to illustrate how the mid-band input matching network, INMB, and the high-band input matching network, INHB, connect to LNA circuit elements.

In LNA design input matching networks are required to perform dual function. To ensure LNA can provide sufficient gain for signal amplification the input impedance presented to the source, Zin, must be sufficiently well matched to the source impedance so that reflection coefficient, □in, is minimised within the frequency band of operation. Source impedance is typically 50 □ and magnitude of input reflection coefficient, □in, is typically required to be less than −10 dB. These values are provided by way of example only and it is not intended to limit the present teaching to exemplary values.

Noise performance of LNA depends on the impedance presented to the LNA looking back towards the source, Zs, and its associated reflection coefficient, □s. It is well known that for a particular LNA there exists an optimum value of source reflection coefficient, □opt. When the source reflection coefficient is made equal to this optimum value the LNA will have it lowest Noise Factor, adding minimum level of noise to the signal.

Input matching networks are required to balance the gain and noise matching requirements. The matching requirements for gain and noise are often conflicting so typically there is a trade-off which makes it difficult to satisfy both requirements over large bands of frequency. To be cost effective input matching networks should require as few components as possible. Typically input matching networks are kept to a single series inductor of appropriate value.

Consider the case of FIG. 16 where mid-band input matching network, INMB, consists of a single series inductor of value, L_{MB} and where high-band input matching network INHB, consists of a single series inductor of value, L_{HB}.

When the mid-band high-gain LNA path is active the switch state and bias voltages are set as per the Table 3.

TABLE 3
Exemplary switch state and bias voltage setting for mid-band
LNA amplification.

| LNA | | | | | | | |
|---|---|---|---|---|---|---|---|
| Gain | SHMB | bypassMB | vgateMB | SHMHB | SHHB | bypassHB | vgateHB |
| High | OFF | OFF | VON | OFF | OFF | OFF | 0 V |

The mid-band input impedance, Zi_{nMB}, is approximately given by Equation 1.

$${Z}_{inMB} = \frac{1}{{sC}_{1}} + \frac{1}{{sC}_{gs 1}} + s ( {L}_{MB} + {L}_{2} ) + \frac{{g}_{m 1}}{{C}_{gs 1}} {L}_{2} \qquad Equation 1$$

### Where:

Z_{inMB} is the mid—band input impedance,
C₁ is mid-band DC blocking capacitance,
Cgs₁ is gate-source capacitance of transistor M1,
g_{M1} is transconductance of transistor M1,
L_{MB} is mid-band input matching inductance,
L₂ is mid-band source degeneration inductance and
s=2π·j·f, f=frequency.

For a 50Ω system, the mid-band input reflection coefficient, Γ_{inMB}, is given by Equation 2.

$${Γ}_{inMB} = \frac{{Z}_{inMB} - 50}{{Z}_{inMB} + 50} \qquad Equation 2$$

### Where:

Γ_{inMB} is the mid-band input reflection coefficient and
Z_{inMB} is the mid—band input impedance,

The impedance presented to the LNA looking towards the source, Z_{sMB}, is approximated for a 50Ω system by Equation 3.

$${Z}_{sMB} = \frac{1}{{sC}_{1}} + s ( {L}_{MB} ) + 50 \qquad Equation 3$$

### Where:

Z_{sMB} is impedance presented to mid—band LNA input looking back towards source,
C₁ is mid-band DC blocking capacitance and
L_{MB} is mid-band input matching inductance.

To achieve best noise performance for mid-band LNA, impedance presented to mid-band LNA should be to

Z_{sMB}=Z_{optMB} Equation 4

### Where:

Z_{sMB} is impedance presented to mid—band LNA input looking back towards source and Z_{optMB} is impedance required to be presented to mid-band LNA input so that optimal noise reflection is achieved.

When the mid-band low-gain LNA bypass path is active the switch state and bias voltages are set as per the Table 4.

TABLE 4
Exemplary switch state and bias voltage setting for mid-band LNA
bypass.

| LNA | | | | | | | |
|---|---|---|---|---|---|---|---|
| Gain | SHMB | bypassMB | vgateMB | SHMHB | SHHB | bypassHB | vgateHB |
| Low | ON | ON | 0 V | ON | ON | OFF | 0 V |

In this case the mid-band input impedance for LNA bypass in a 50Ω System, Z_{bypassMB}, is approximately given by Equation 5.

Z_{bypassMB}=(R_{onMB}+(R_{SHMHB}/50))/sL_{MB}≅R_{onMB}+(R_{SHMHB}/50), Equation 5.

### Where:

R_{onMB} is on-resistance of mid-band bypass switch,
R_{SHMHB} is on-resistance of output shunt switch and
L_{MB} is mid-band input matching inductance.

It will be understood by those skilled in the art of RF Switch and LNA design that frequency dependence of impedance elements of terms in Equations 1-5 results in limited range of frequencies over which these requirements can be simultaneously satisfied. It will further be understood that Equations 1 and 5 illustrate how input impedance requirements in LNA active mode and bypass mode have been decoupled, extending range of frequencies over which these requirements can be simultaneously satisfied. Similar equations can be derived for high-band LNA.

When mid-band high-gain LNA path is active the switch state and bias voltages are set as per the Table 5.

TABLE 5
Exemplary switch state and bias voltage setting for high-band LNA amplification.

| LNA Gain | SHMB | bypassMB | vgateMB | SHMHB | SHHB | bypassHB | vgateHB |
|---|---|---|---|---|---|---|---|
| High | OFF | OFF | 0 V | OFF | OFF | OFF | VON |

The high-band input impedance, Zi_{nHB}, is approximately given by Equation 6.

$${Z}_{inHB} = \frac{1}{{sC}_{3}} + \frac{1}{{sC}_{gs 3}} + s ( {L}_{MB} + {L}_{3} ) + \frac{{g}_{m 3}}{{c}_{gs 3}} {L}_{3} \qquad Equation 6$$

### Where:

Z_{inHB} is the high—band input impedance,
C₃ is high-band DC blocking capacitance,
Cgs₃ is gate-source capacitance of transistor M3,
g_{M3} is transconductance of transistor M3,
L_{HB} is high-band input matching inductance,
L₃ is high-band source degeneration inductance and
s=2π·j·f, f=frequency.

For a 50Ω system, the high-band input reflection coefficient, Γ_{inHB}, is given by Equation 7.

$${Γ}_{inHB} = \frac{{Z}_{inHB} - 50}{{Z}_{inHB} + 50} \qquad Equation 7$$

### Where:

Γ_{inHB} is the high-band input reflection coefficient and
Z_{inHB} is the high—band input impedance,

The impedance presented to the LNA looking towards the source, Z_{sHB}, is approximated for a 50Ω system by Equation 8.

$${Z}_{sHB} = \frac{1}{{sC}_{3}} + s ( {L}_{HB} ) + 50 \qquad Equation 8$$

### Where:

Z_{sHB} is impedance presented to high—band LNA input looking back towards source,
C₃ is high-band DC blocking capacitance and
L_{HB} is high-band input matching inductance.

To achieve best noise performance for high-band LNA, impedance presented to high-band LNA should be to

Z_{sHB}=Z_{optHB} Equation 9

### Where:

Z_{sHB} is impedance presented to high—band LNA input looking back towards source and Z_{optHB} is impedance required to be presented to high-band LNA input so that optimal noise reflection is achieved.

When high-band low-gain LNA bypass path is active the switch state and bias voltages are set as per the Table 6.

TABLE 6
Exemplary switch state and bias voltage setting for high-band LNA bypass.

| LNA | | | | | | | |
|---|---|---|---|---|---|---|---|
| Gain | SHMB | bypassMB | vgateMB | SHMHB | SHHB | bypassHB | vgateHB |
| Low | ON | OFF | 0 V | ON | ON | ON | 0 V |

In this case the mid-band input impedance for LNA bypass in a 50Ω system, Z_{bypassHB}, is approximately given by Equation 10.

Z_{bypassHB}=(R_{onHB}+(R_{SHMHB}/50))/sL_{HB}≅R_{onHB}+(R_{SHMHB}/50) Equation 10.

### Where:

R_{onHB} is on-resistance of high-band bypass switch,
R_{SHMHB} is on-resistance of output shunt switch and
L_{HB} is high-band input matching inductance.

It will be understood by those skilled in the art of RF Switch and LNA design that frequency dependence of impedance elements of terms in Equations 6-10 results in limited range of frequencies over which these requirements can be simultaneously satisfied. It will further be understood that Equations 6 and 10 illustrate how input impedance requirements in LNA active mode and bypass mode have been decoupled, extending range of frequencies over which these requirements can be simultaneously satisfied.

It will be further understood how separation of requirements for mid-band as described by Equations 1-5 and those for high-band as described by Equations 6-10 even further extends frequency range over which requirements can be simultaneously met by decoupling the requirements for mid-band from those of high-band.

The RF switching circuits described with reference to FIGS. 13-16 may be fabricated on a semiconductor substrate. It is envisaged that the RF switching circuits may be provided on a Silicon-On-Insulator structure similar to that described with reference FIG. 11. The RF switching circuits may be fabricated using semiconductor processing techniques that are well known in the art and may include for example, but not limited to, deposition, implantation, diffusion, patterning, doping, and etching. Since these semiconductor processing techniques are known in the art, it is not intended to describe them further. A person skilled in the art would understand how to fabricate the RF switching circuit 200 on a substrate using these known techniques. The method may comprise providing an RF switch on a substrate having multiple RF inputs and two or more switch outputs; providing a low noise amplifier (LNA) on the substrate having two or more amplification branches, each amplification branch being associated with a corresponding switch output; and providing a bypass switching mechanism on the substrate configured for selectively bypassing the amplification branches.

While the present teaching has been described with reference to exemplary arrangements and circuits it will be understood that it is not intended to limit the teaching of the present teaching to such arrangements as modifications can be made without departing from the spirit and scope of the present invention. In this way it will be understood that the present teaching is to be limited only insofar as is deemed necessary in the light of the appended claims. It will be appreciated by those of ordinary skill in the art that a Low Noise Amplifier (LNA) is typically one of the first active elements providing amplification of a signal received at an antenna of a wireless receive system. An LNA is characterised by its Noise Figure and Gain among other parameters. In systems for mobile phone and WiFi applications an LNA is typically required to have a Noise Figure of less than 1 or 2 dB depending on frequency of operation and Gain between 10 and 20 dB within its frequency range of operation. Frequency bands and receive system requirements within those bands are specified by the 3^{rd} Generation Partnership Project, 3GPP consortium for cellular systems. The RF Spectrum is sub-divided into bands which is a range of frequencies within which information must be transmitted or received. Bands that fall within range of 1.8 GHz-2.3 GHz are typically referred to as mid-band frequencies for cellular applications. Bands that fall within range of 2.3-2.7 GHz are typically referred to as high-band frequencies for cellular applications.

Similarly the words comprises/comprising when used in the specification are used to specify the presence of stated features, integers, steps or components but do not preclude the presence or addition of one or more additional features, integers, steps, components or groups thereof.

What is claimed is:

1. An RF switching circuit comprising
an RF switch having multiple RF inputs and two or more switch outputs;
a low noise amplifier (LNA) having two or more amplification branches, each amplification branch being associated with a corresponding switch output; and
a bypass switching mechanism configured for selectively bypassing the amplification branches.

2. An RF switching circuit as claimed in claim 1, further comprising two or more input matching networks; each input matching network being associated with a corresponding amplification branch.

3. An RF switching circuit as claimed in claim 2, wherein the bypass switching mechanism is configured for selectively bypassing the respective input matching networks.

4. An RF switching circuit as claimed in claim 3, wherein each input matching network is operably coupled between a corresponding one of the switch outputs and a corresponding one of the amplification branches.

5. An RF switching circuit as claimed in claim 4, wherein the bypass switching mechanism comprises one or more bypass switches.

6. An RF switching circuit as claimed in claim 5, wherein each amplification branch is associated with a corresponding bypass switch.

7. An RF switching circuit as claimed in claim 6, wherein each bypass switch is operably coupled between a corresponding one of the switch outputs and an output of the LNA.

8. An RF switching circuit as claimed in claim 1, wherein each amplification branch is optimised for a corresponding frequency band.

9. An RF switching circuit as claimed in claim 1, wherein each amplification branch is optimised for a predetermined cellular frequency band.

10. An RF switching circuit as claimed in claim 1, wherein one of the amplification branches is optimised for a first frequency band and another one of the amplification branched is optimised for a second frequency band.

11. An RF switching circuit as claimed in claim 10, wherein the first frequency band and the second frequency bands have different frequency ranges.

12. An RF switching circuit as claimed in claim 10, wherein the first frequency band is a mid-band frequency cellular range and the second frequency band is a high-band frequency cellular range.

13. An RF switching circuit as claimed in claim 10, wherein the first frequency band has a frequency range of 1.8 GHz to 2.3 GHz.

14. An RF switching circuit as claimed in claim 10, wherein the second frequency band has a frequency range of 2.3 GHz to 2.7 GHz.

15. An RF switching circuit as claimed in claim 2, wherein each input matching network is optimised for a corresponding frequency band.

16. An RF switching circuit as claimed in claim 15, wherein each input matching network comprises one or more frequency dependent components.

17. An Rf switching circuit as claimed in claim 16, wherein each input matching networks comprises one or more inductive elements.

18. An RF switching circuit as claimed in claim 1, wherein each amplification branch comprises an input DC blocking capacitor.

19. An RF switching circuit as claimed in claim 18, wherein each input DC blocking capacitor is operably coupled to a gate of a first transistor.

20. An RF switching circuit as claimed in claim 19, wherein a first DC bias voltage source is operably coupled to the gate of the first transistor via a resisitive load.

21. An RF switching circuit as claimed in claim 20, further comprising a cascode transistor operably coupled to the first transistor which together form an amplification stage.

22. An RF switching circuit as claimed in claim 21, wherein a second DC bias voltage source is operably coupled to the gate of the cascode transistor.

23. An RF switching circuit wherein the cascode transistor is operably coupled to an inductor.

24. An RF switching circuit as claimed in claim 1, further comprising an output DC blocking capacitor operably coupled to the two or more amplification branches and an output of the LNA.

25. An RF switching circuit as claimed in claim 18, wherein each amplification branch comprises an input shunt switch operably coupled to the input DC blocking capacitor and ground.

26. An RF switching circuit as claimed in claim 25, wherein each input shunt switch provides an ESD discharge path to ground for an ESD event occurring on the corresponding amplification branch.

27. An RF switching circuit as claimed in claim 25, wherein each input shunt switch provides signal attenuation.

28. An RF switching circuit as claimed in claim 25, wherein the input shunt switch is open when the corresponding amplification branch is active.

29. An RF switching circuit as claimed in claim 1, wherein the RF switch is a multi-pole multi-throw switch.

30. An RF switching circuit as claimed in claim 1, wherein the RF switch is a single-pole multi-throw switch.

31. An RF switching circuit as claimed in claim 1, wherein the LNA has multiple inputs and a single output.

32. An RF switching circuit as claimed in claim 31, wherein the poles of the RF switch are coupled to inputs of LNA.

33. An RF switching circuit, wherein the bypass switching mechanism is configured to selectively connect a predetermined pole of the RF switch to the output of LNA.

34. An RF switching circuit as claimed in claim 24, further comprising an output shunt switch operably coupled to the output DC blocking capacitor and ground.

35. An RF switching circuit as claimed in claim 34, wherein the output shunt switch provides an ESD discharge path to ground for an ESD event occurring on the output of the LNA.

36. An RF switching circuit as claimed in claim 34, wherein the output shunt switch provides signal attenuation.

37. An RF switching circuit as claim 19, wherein each amplification branch comprises a degeneration inductor operably coupled to the first transistor.

38. An RF switching circuit as claimed in claim 1, wherein the low noise amplifier has a Noise Figure of less than 1 dB.

39. An RF switching circuit as claimed in claim 1, wherein the low noise amplifier has a Noise Figure of less than 2 dB.

40. An RF switching circuit as claimed in claim 1, wherein the low noise amplifier is configured to provide a gain of between 10 dB and 20 dB within its frequency range of operation.

41. A semiconductor substrate having an RF switching circuit fabricated thereon, wherein the RF switching circuit comprises:
an RF switch having multiple RF inputs and two or more switch outputs;
a low noise amplifier (LNA) having two or more amplification branches, each amplification branch being associated with a corresponding switch output; and
a bypass switching mechanism configured for selectively bypassing the amplification branches.

42. A method of fabricating an RF switching circuit as claimed in claim 1, the method comprising:
providing an RF switch on a substrate having multiple RF inputs and two or more switch outputs;
providing a low noise amplifier (LNA) on the substrate having two or more amplification branches, each amplification branch being associated with a corresponding switch output; and
providing a bypass switching mechanism on the substrate configured for selectively bypassing the amplification branches.

43. An RF switching circuit comprising:
a low noise amplifier (LNA) having one or more amplification branches, each amplification branch being associated with a corresponding RF switch output and a corresponding input matching network; and
a bypass switching mechanism configured for selectively bypassing the respective amplification branches and the corresponding input matching network.
